(19) United States
(12) Patent Application Publication
(10) Pub. No.: US 2008/0274626 A1
(43) Pub. Date: Nov. 6, 2008

(54) METHOD FOR DEPOSITING A HIGH QUALITY SILICON DIELECTRIC FILM ON A GERMANIUM SUBSTRATE WITH HIGH QUALITY INTERFACE

(76) Inventors: Frederique Glowacki, Grenoble (FR); Laurent Vandroux, Saint Nazaire Ies Eymes (FR); Rajesh Mani, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/744,778

(22) Filed: May 4, 2007

(51) Int. Cl. H01L 21/31

(52) U.S. Cl. 438/787; 438/778; 438/791; 257/E21.24

(57) ABSTRACT

In certain embodiments methods for depositing materials on substrates, and more particularly, methods for depositing dielectric layers, such as silicon oxides or silicon oxynitrides, on germanium substrates are provided. The methods involve depositing a barrier layer on the germanium substrate to prevent oxidation of the germanium substrate when forming a dielectric layer on the germanium substrate. In certain embodiments, a silicon layer is deposited on the germanium substrate to form a barrier layer. In certain embodiments, nitridation of the germanium substrate forms a GeₓN_{y} layer which functions as a barrier layer. In certain embodiments, a silicon nitride layer is deposited on the germanium substrate to form a barrier layer.

### BACKGROUND OF THE INVENTION

1. Field of the Invention

Embodiments of the present invention as recited in the claims generally relate to methods for depositing materials on substrates, and more particularly, to methods for depositing dielectric layers, such as silicon oxides or silicon oxynitrides, on germanium or germanium-based substrates.

2. Description of the Related Art

As the dimensions of transistors and other semiconductor structures become smaller, the demand for high quality semiconductor on insulator structures for very large scale integration applications has become an important part of semiconductor fabrication. Semiconductor on insulator technology allows for this reduced structure size while providing greater isolation between devices. This isolation between devices reduces problems associated with electromagnetic interference and parasitic capacitance between the structures which are magnified as the size of circuits is reduced.

Because silicon is the dominant semiconductor material in present day integrated circuit devices, much effort has been focused on improving silicon on insulator fabrication techniques. However, there has also been an increased interest in forming non-silicon semiconductor on insulator structures, such as germanium on insulator (GeOI) structures, for example. Due to silicon's scaling limitations many chipmakers are evaluating engineered germanium on insulator type substrates to enhance device performance. Germanium based materials show great promise for future high-speed logic applications by allowing electrons to flow through the material at a faster rate, potentially speeding transistor switching by 3× to 4× over silicon.

Although the fundamental speed advantage of germanium over silicon, has been known for some time, the unstable nature of germanium oxides (GeOₓ) formed when depositing insulators on germanium has made the use of germanium in most devices unfeasible.

Therefore, there is a need for a deposition process for depositing a dielectric film on a germanium substrate while reducing the formation of germanium oxides that are of low quality, unstable, and not suitable for device applications.

### SUMMARY OF THE INVENTION

In accordance with the foregoing, embodiments of the present invention as recited in the claims, generally provide methods for depositing materials on substrates, and more particularly, to methods for depositing dielectric layers, such as silicon oxides or silicon oxynitrides, on germanium substrates. In certain embodiments a method for forming a dielectric film on a germanium substrate is provided. A germanium substrate is provided. A barrier layer is formed on the germanium substrate. A dielectric layer is formed on the substrate.

In certain embodiments a method for forming a dielectric film on a substrate is provided. A germanium substrate is provided. A silicon layer is deposited on the substrate. A silicon dioxide layer is formed on the silicon layer.

In certain embodiments a method of forming a dielectric film on a substrate is provided. A germanium substrate is provided. The germanium substrate is exposed to a plasma comprising a nitrogen source to form a germanium nitride layer. A dielectric layer is formed on the germanium nitride layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an exemplary process sequence for forming a dielectric layer on a germanium substrate according to certain embodiments described herein;

FIG. 2 illustrates an exemplary process sequence for forming a dielectric layer on a germanium substrate using a silicon barrier layer therebetween according to certain embodiments described herein;

FIG. 3 illustrates an exemplary process sequence for forming a dielectric layer on a germanium substrate using a GeₓN_{y} barrier layer therebetween according to certain embodiments described herein;

FIG. 4 illustrates an exemplary process sequence for forming a dielectric layer on a germanium substrate using a silicon nitride barrier layer therebetween according to certain embodiments described herein; and

FIG. 5 is a schematic view of an integrated processing system capable of performing the processes disclosed herein.

To facilitate understanding, identical reference numerals have been used, where possible, to designate identical elements that are common to the figures. It is contemplated that elements and/or process steps of one or more embodiments may be beneficially incorporated in one or more other embodiments without additional recitation.

### DETAILED DESCRIPTION

In certain embodiments methods for depositing materials on substrates, and more particularly, methods for depositing dielectric layers, such as silicon oxides or silicon oxynitrides, on germanium or germanium-based substrates are provided. The methods involve depositing a barrier layer on the germanium substrate to prevent oxidation of the germanium substrate when forming a dielectric layer on the germanium substrate. In certain embodiments, a silicon layer is deposited on the germanium substrate to form a barrier layer. In certain embodiments, nitridation of the germanium substrate forms a GeₓN_{y} layer which functions as a barrier layer. In certain embodiments, a silicon nitride layer is deposited on the germanium substrate to form a barrier layer.

As used herein, a “substrate surface” refers to any substrate or material surface formed on a substrate upon which film processing is performed. For example, a substrate surface on which processing may be performed include materials such as germanium, germanium on insulator (GeOI), alloys of silicon and germanium, such as silicon-germanium (SiGe), dielectric materials, silicon, silicon oxide, strained silicon, silicon on insulator (SOI), carbon doped silicon oxides, silicon nitride, doped silicon, gallium arsenide, glass, sapphire, and any other materials such as metals, metal nitrides, metal alloys, and other conductive materials, depending on the application. Barrier layers, metals or metal nitrides on a substrate surface include silicon, germanium nitride, silicon nitride, titanium, titanium nitride, tungsten nitride, tantalum, and tantalum nitride. Substrates may have various dimensions, such as 200 mm or 300 mm diameter wafers, as well as, rectangular or square substrate.

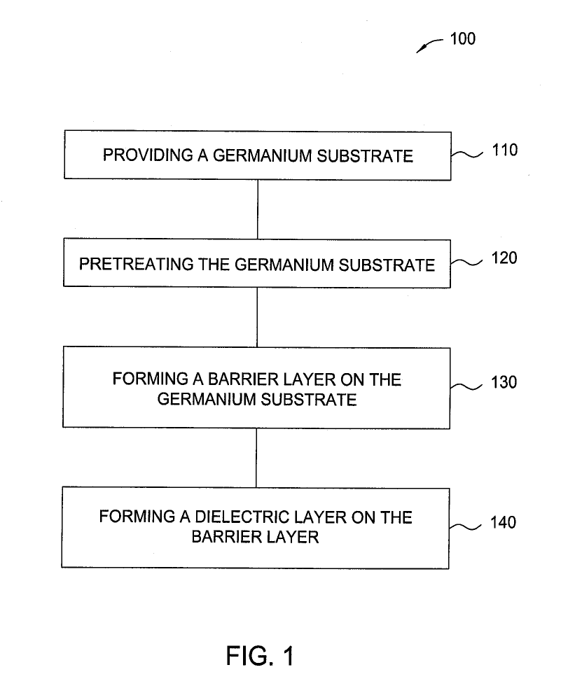

FIG. 1 illustrates an exemplary process sequence 100 for forming a dielectric layer, such as a silicon oxide or a silicon oxynitride layer, on a germanium substrate according to certain embodiments described herein. In step 110, a substrate comprising germanium is provided. In step 120, the surface of the substrate is cleaned. In step 130, a barrier layer is formed on the substrate. In step 140, a dielectric layer is deposited on the barrier layer.

In step 110, a substrate comprising germanium is provided. In certain embodiments the substrate may comprise epitaxially or heteroepitaxially deposited germanium. In certain embodiments, the substrate may comprise germanium heteroepitaxially deposited on a silicon substrate. The term germanium substrate may include germanium compounds as well as substrates consisting of essentially pure germanium.

In step 120, an optional pretreatment step may be performed. The substrate may be pretreated before forming the barrier layer in order to have termination with a variety of functional groups such as hydroxyls (OH), alkoxy (OR, where R=Me, Et, Pr or Bu), haloxyls (OX, where X═F, Cl, Br or I), halides (F, Cl, Br or I), oxygen radicals, aminos (NH or NH₂) and amidos (NR or NR₂, where R═H, Me, Et, Pr or Bu). A pretreatment may be effected by administering a reagent, such as NH₃, B₂H₆, SiH₄, Si₂H₆, HF, HCl, O₂, O₃, H₂O, H₂O/O₂, H₂O/H₂, H₂O₂, H₂, atomic-H, atomic-N, atomic-O, alcohols or amines. In certain embodiments, the pretreatment may involve a presoak with a reagent prior to depositing the barrier layer. The presoak may involve exposing the substrate surface to the reagent for a period of time from about 5 seconds to about 120 seconds, preferably from about 5 seconds to about 30 seconds. In one example, the substrate surface is exposed to water vapor for 15 seconds prior to depositing the barrier layer. In certain embodiments, the pretreatment step includes IMEC Clean #2 (SPM/O₃-HF-Rinse, O₃ Marangoni Dry, HC1). In certain embodiments, the pre-treatment step may include polishing, etching, reduction, oxidation, hydroxylation, annealing and/or baking. In certain embodiments, a HF-last treatment is performed to passivate the substrate surface followed by the storage of the substrate surface under vacuum to prevent germanium oxidation and contamination.

In step 130, a barrier layer is formed on the germanium substrate. In certain embodiments, the barrier layer comprises a silicon layer. In certain embodiments, the barrier layer comprises a germanium nitride layer, GeₓN_{y}. In certain embodiments, the barrier layer comprises a silicon nitride layer. In certain embodiments, other suitable barrier materials such as titanium, titanium nitride, tungsten nitride, tantalum, and tantalum nitride may be used.

In step 140, a dielectric layer is deposited on the barrier layer. In certain embodiments, the dielectric layer preferably comprises materials such as silicon dioxide (SiO₂), or a high-K dielectric material having a dielectric constant greater than 4.0, such as silicon oxynitride (SiON). In certain embodiments, other dielectric materials such as silicon nitride (SiN), hafnium oxide (HfO₂), hafnium silicate (HfSiO₂), hafnium silicon oxynitride (HfSiON), zirconium oxide (ZrO₂), zirconium silicate (ZrSiO₂), barium strontium titanate (BaSrTiO₃ or BST), and lead zirconium titanate (Pb(ZrTi)O₃, or PZT) may be formed. The dielectric material may have a variety of compositions that are homogenous, heterogeneous, graded and/or multiple layered stacks or laminates. The dielectric material may include combinations of hafnium, zirconium, titanium, tantalum, lanthanum, aluminum, silicon, oxygen and/or nitrogen.

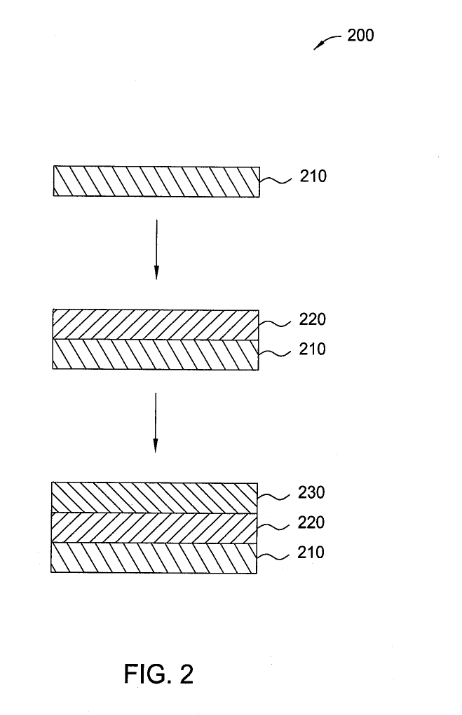

FIG. 2 illustrates an exemplary process sequence 200 for forming a dielectric layer on a germanium substrate using a silicon barrier layer therebetween according to certain embodiments described herein. A continuous silicon layer 220 is deposited on a germanium substrate 210 by conventional deposition techniques such as ALD, chemical vapor deposition (CVD), physical vapor deposition (PVD), low pressure chemical vapor deposition (LPCVD), atomic layer epitaxy process (ALE), plasma enhanced chemical vapor deposition (PECVD), thermal techniques and combinations thereof. In a preferred embodiment, the silicon layer 220 is deposited by LPCVD. One embodiment of an LPCVD chamber which may be used to perform the current invention is described in FIGS. 1-3 and col. 3: line 1 through col. 8: line 61 of commonly assigned U.S. Pat. No. 6,726,955, entitled METHOD OF CONTROLLING THE CRYSTAL STRUCTURE OF POLYCRYSTALLINE SILICON, which is herein incorporated by reference to the extent it does not conflict with the current specification.

In certain embodiments, deposition of the amorphous silicon layer using LPCVD is achieved by exposing the germanium substrate to nitrogen gas at a bottom flow rate from about 2,000 sccm to about 10,000 sccm, for example, about 3,500 sccm, nitrogen gas at a top flow rate from about 2,000 sccm to about 10,000 sccm, for example, about 5,000 sccm, and a silicon containing gas at a flow rate from about 10 sccm to about 100 sccm, for example, about 30 sccm, at a temperature from about 500° C. to about 900° C., for example, about 700° C., a pressure from about 200 Torr to about 300 Torr, for example, about 275 Torr, for a period from about 5 second to about 60 second, for example, about 10 seconds. The silicon layer 220 is generally deposited with a film thickness from about 5 Å to about 2,000 Å, preferably from about 10 Å to about 500 Å and more preferably from about 20 Å to about 100 Å, for example, about 70 Å. The silicon containing gas may be selected from the group comprising silane (SiH₄), disilane (Si₂H₆), silicon tetrachloride (SiCl₄), dichlorosilane (Si₂Cl₂H₂), trichlorosilane (SiCl₃H), and combinations thereof. In certain embodiments, the germanium substrate may be pretreated before depositing the silicon layer 220 as described above.

In certain embodiments, the amorphous silicon layer is deposited using a PECVD system such as the FLEXSTAR® system available from Applied Materials, Inc. of Santa Clara, Calif. PECVD deposition of the amorphous silicon layer may be performed using the aforementioned process conditions with a temperature of 400° C. as well as process conditions known to one of ordinary skill in the art.

The dielectric layer 230 is formed on the silicon layer 220. The dielectric layer 230 is preferably a silicon dioxide layer or a silicon oxynitride layer. In certain embodiments, the dielectric layer 230 is formed by annealing the silicon layer 220 in an oxygen containing atmosphere. In certain embodiments, the dielectric layer 230 is deposited on the silicon layer 220 using a CVD or LPCVD process. In certain embodiments, the dielectric layer 230 is formed on the silicon layer 220 using an ALD process. In certain embodiments, the thickness of the dielectric layer is limited by the allowed thermal budget of the technique chosen to form the dielectric layer on the silicon layer.

In certain embodiments the substrate 210 is transferred to an anneal chamber, such as the RADIANCE™ rapid thermal processing (RTP) chamber available from Applied Materials, Inc., located in Santa Clara, Calif., for a post deposition annealing of the silicon layer 220 in an oxygen containing atmosphere. A post deposition anneal is performed where the substrate is annealed at a temperature from about 500° C. to about 1,200° C., preferably from about 550-700° C. for a time period from about 1 second to about 240 seconds, preferably from about 30 seconds to about 90 seconds, for example, at about 650° C. for about 60 seconds. Generally, the anneal chamber atmosphere contains at least one anneal gas, such as O₂, N₂, NH₃, N₂H₄, NO, N₂O, or combinations thereof. The anneal chamber is maintained at a pressure from about 5 Torr to about 100 Torr, for example, at about 50 Torr.

In certain embodiments, the dielectric layer 230 is deposited on the silicon layer 220 using a LPCVD process. In certain embodiments, the dielectric layer 230 is formed on the silicon layer 220 by exposing the substrate to nitrogen gas at a bottom flow rate of about 2,000 sccm to about 10,000 sccm, for example, about 3,500 sccm, nitrogen gas at a top flow rate from about 2,000 sccm to about 10,000 sccm, for example, about 5,000 sccm, silicon containing gas at a flow rate of about 10 sccm to about 30 sccm, for example about 15 sccm, and an oxygen containing gas at a flow rate of about 1,000 sccm to about 10,000 sccm, for example, about 3,000 sccm, at a temperature from about 500° C. to about 1,000° C., for example, about 700° C., a pressure from about 200 Torr to about 300 Torr, for example, about 275 Torr, for a period of between about 100 seconds and about 300 second, for example, about 155 seconds. The oxygen containing gas may comprise O₂, NO, and N₂O, or combinations thereof. The silicon containing gas may be selected from the group comprising silane (SiH₄), disilane (Si₂H₆), silicon tetrachloride (SiCl₄), dichlorosilane (Si₂Cl₂H₂), trichlorosilane (SiCl₃H), and combinations thereof.

In certain embodiments, the dielectric layer 230 is a silicon oxynitride layer. In certain embodiments, the silicon oxynitride layer is formed by nitriding the silicon oxide layer as describe below, to convert the silicon dioxide film into a silicon oxynitride film.

The dielectric layer 230 is generally deposited with a film thickness from about 10 Å to about 2,500 Å, preferably from about 500 Å to about 2,000 Å and more preferably from about 1,000 Å to about 1,600 Å, for example, about 1,500 Å. Although the dielectric layer 230 is generally, either a silicon dioxide layer or a silicon oxynitride layer, the dielectric layer 230 may comprise other dielectric layers as described above.

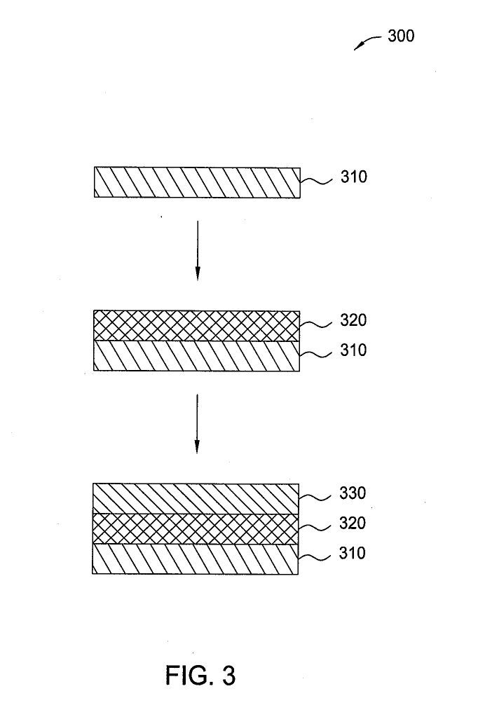

FIG. 3 illustrates an exemplary process sequence 300 for forming a dielectric layer on a germanium substrate using a GeₓN_{y} barrier layer therebetween according to certain embodiments described herein. A germanium substrate 310 is provided. The germanium substrate 310 undergoes a nitridation process to form a GeₓN_{y} layer 320. In certain embodiments, the nitridation process may be a Decoupled Plasma Nitridation (DPN) process. During the DPN process, the substrate is bombarded with atomic-N formed by co-flowing N₂ and a noble gas plasma such as argon. Besides N₂, other nitrogen-containing gases may be used to form the nitrogen plasma, such as NH₃, hydrazines (e.g., N₂H₄ or MeN₂H₃), amines (e.g., Me₃N, Me₂NH or MeNH₂), anilines (e.g., C₅H₅NH₂), azides (e.g., MeN₃ or Me₃SiN₃), N₂O, and NO. Other noble gases that may be used in a DPN process include helium, neon, and xenon. The nitridation process proceeds at a time period from about 10 seconds to about 360 seconds, preferably from about 30 seconds to about 180 seconds, for example, about 120 seconds. Also, the nitridation process is conducted with a plasma power setting at about 300 watts to about 2,700 watts and a pressure from about 10 mTorr to about 100 mTorr. The nitrogen has a flow rate from about 0.1 slm to about 1.0 slm. The individual and total gas flows of the processing gases may vary based upon a number of processing factors, such as the size of the processing chamber, the temperature of the processing chamber, and the size of the substrate being processed. In a preferred embodiment, the nitridation process is a DPN process and includes a plasma formed by co-flowing Ar and N₂. The GeₓN_{y} layer 320 is generally formed with a film thickness from about 10 Å to about 1,000 Å, preferably from about 20 Å to about 500 Å and more preferably from about 50 Å to about 200 Å, for example, about 100 Å.

Dielectric layer 330 is deposited on the GeₓN_{y} barrier layer 320. The dielectric layer 330 is preferably a silicon oxide or silicon oxynitride layer. In certain embodiments wherein the dielectric layer 330 comprises a silicon oxide layer, the silicon oxide layer may be formed by depositing a continuous silicon layer by conventional deposition techniques such as ALD, chemical vapor deposition (CVD), physical vapor deposition (PVD), low pressure chemical vapor deposition (LPCVD), thermal techniques and combinations thereof, as described above. In certain embodiments, deposition of the silicon layer is followed by an oxidation step.

In certain embodiments where the dielectric layer 330 is a silicon oxynitride layer, a plasma nitridation step is performed to convert the silicon dioxide film into silicon oxynitride film. In certain embodiments, the plasma nitridation process used is Decoupled Plasma Nitridation (DPN). DPN is a technology using inductive coupling to generate nitrogen plasma and incorporate a high level of nitrogen into an oxide film. In DPN, a surface film, e.g., an SiO₂ film, is bombarded with nitrogen ions which break the SiO₂ film forming a silicon oxynitride film. In one embodiment, DPN is performed in a chamber with pressure ranging from about 5 mTorr to about 20 mTorr, with a plasma power from about 200 to about 800 Watts. The nitrogen gas may be flown into the chamber at a flow rate ranging from about 100 sccm to about 200 sccm. In one embodiment, the DPN uses a pulse radio frequency plasma process at about 10-20 MHz and pulse at about 5-15 kHz. The DPN process parameters can be modified depending on the chamber size and volume, and the desired thickness of the dielectric film. In certain embodiments, the silicon oxynitride film may be subject to a post nitridation anneal step.

The dielectric layer 330 is generally deposited with a film thickness from about 10 Å to about 2,500 Å, preferably from about 500 Å to about 2,000 Å and more preferably from about 1,000 ∈ to about 1,600 Å, for example, about 1,500 Å. Although the dielectric layer 330 is generally, either a silicon dioxide layer or a silicon oxynitride layer, dielectric layer 330 may comprise other dielectric layers as described above.

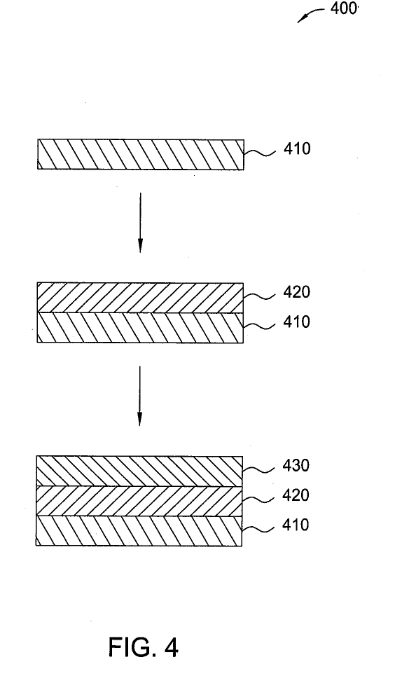

FIG. 4 illustrates an exemplary process sequence 400 for forming a dielectric layer on a germanium substrate using a silicon nitride barrier layer therebetween according to certain embodiments described herein. A germanium substrate 410 is provided. In certain embodiments, the germanium substrate 410 may be pretreated before depositing the silicon nitride layer 420 as described above. A silicon nitride layer (SiₓN_{y}) 420 is deposited on the germanium substrate 410 by conventional deposition techniques such as ALD, chemical vapor deposition (CVD), physical vapor deposition (PVD), low pressure chemical vapor deposition (LPCVD), thermal techniques and combinations thereof. In a preferred embodiment, the silicon nitride layer 420 is deposited by LPCVD.

In one embodiment, the substrate is heated to a temperature of between about 300° C. and about 500° C., for example 450° C. A nitrogen and carbon chemical, for example, (CH₃)₃N, is provided at a rate between about 100 sccm to about 3000 sccm, for example about 1000 sccm to about 2000 sccm. A Si-source chemical, for example, trisilylamine, is provided at a rate between about 1 sccm to about 300 sccm, or in another example, at a rate between about 13 sccm to about 130 sccm. In embodiments where a carrier gas is combined with the Si-source chemical, the total rate for a liquid source is about 10 sccm to 10,000 sccm. Generally, a flow ratio for (CH₃)₃N to trisilylamine is maintained at a ratio of about 10:1 to about 1:1. In one embodiment, the (CH₃)₃N to trisilylamine flow ratio is 3:1. Other examples of suitable process conditions for depositing a SiₓN_{y} layer are described in U.S. patent application Ser. No. 11/155,646, entitled METHOD FOR SILICON BASED DIELECTRIC CHEMICAL VAPOR DEPOSITION, published as U.S. 2006/0286818, which is herein incorporated by reference.

The silicon nitride layer is generally deposited with a film thickness from about 10 Å to about 1,000 Å, preferably from about 20 Å to about 500 Å and more preferably from about 50 Å to about 200 Å, for example, about 100 Å.

Dielectric layer 430 is deposited on the SiₓN_{y} barrier layer 420. The dielectric layer 430 is preferably a silicon oxide or silicon oxynitride layer. In certain embodiments wherein the dielectric layer 430 comprises a silicon oxide layer, the silicon oxide layer may be formed by the techniques described above. In certain embodiments where the dielectric layer 430 comprises a silicon oxynitride layer a plasma nitridation step may be performed to convert the silicon dioxide film into silicon oxynitride film as described above. The dielectric layer 430 is generally deposited with a film thickness from about 10 Å to about 1,000 Å, preferably from about 20 Å to about 500 Å and more preferably from about 50 Å to about 200 Å, for example, about 100 Å. Although the dielectric layer 430 is generally, either a silicon dioxide layer or a silicon oxynitride layer, dielectric layer 430 may comprise other dielectric layers as described above.

### EXAMPLES

### Example 1

A silicon dioxide layer was formed on a germanium substrate with a silicon barrier layer therebetween. Initially a 200 mm germanium substrate formed by epitaxially depositing germanium was exposed to a pretreatment cleaning step using IMEC Clean #2 (SPM/O₃-HF-Rinse, O₃ Marangoni Dry, HC1). During the duration between the wet-pretreatment and wafer loading, the substrate was maintained in a controlled low pressure atmosphere for less than one hour. The substrate was placed into a SiNgen® LPCVD chamber, available from Applied Materials, Inc. of Santa Clara, Calif., where a thin continuous amorphous silicon layer was deposited on the surface of the germanium substrate. Deposition of the amorphous silicon layer is achieved by exposing the germanium substrate to N₂ at a bottom flow rate of 3,500 sccm, N₂ at a top flow rate of 5,000 sccm, and SiH₄ at a flow rate of 30 sccm, at a temperature of 700° C., a pressure of 275 Torr, for a period of 10 seconds to deposit 21 Å of silicon at a deposition rate of 127 Å/min. A silicon dioxide layer was then deposited on the silicon layer by flowing N₂ at a bottom flow rate of 3,500 sccm, N₂ at a top flow rate of 5,000 sccm, SiH₄ at a flow rate of 15 sccm, and N₂O at a flow rate of 3,000 sccm, at a temperature of 700° C., a pressure of 275 Torr, for a period of 155 seconds to deposit 1521 Å of silicon oxide at a rate of 589 Å/min.

### Example 2

A silicon dioxide layer was formed on a germanium substrate with a silicon barrier layer therebetween. Initially a 200 mm germanium substrate formed by epitaxially depositing germanium was exposed to a pretreatment cleaning step using IMEC Clean #2 (SPM/O₃-HF-Rinse, O₃ Marangoni Dry, HC1). During the duration between the wet-pretreatment and wafer loading, the substrate was maintained in a controlled low pressure atmosphere for less than one hour. The substrate was placed into a SiNgen® LPCVD chamber, available from Applied Materials, Inc. of Santa Clara, Calif., where a thin continuous amorphous silicon layer was deposited on the surface of the germanium substrate. Deposition of the amorphous silicon layer was achieved by exposing the germanium substrate to N₂ at a bottom flow rate of 3,500 sccm, N₂ at a top flow rate of 5,000 sccm, and SiH₄ at a flow rate of 30 sccm, at a temperature of 700° C., a pressure of 275 Torr, for a period of 30 seconds to deposit 63 Å of silicon at a deposition rate of 127 Å/min. A silicon dioxide layer was then deposited on the silicon layer by flowing N₂ at a bottom flow rate of 3,500 sccm, flowing N₂ at a top flow rate of 5,000 sccm, flowing SiH₄ at a flow rate of 15 sccm, and 3,000 sccm of N₂O, at a temperature of 700° C., a pressure of 275 Torr, for a period of 155 seconds to deposit 1521 Å of silicon oxide at a rate of 589 Å/min.

### Example 3

A silicon dioxide layer was formed on a germanium substrate with a silicon barrier layer therebetween. Initially a 200 mm germanium substrate formed by epitaxially depositing germanium was exposed to a pretreatment cleaning step using IMEC Clean #2 (SPM/O₃-HF-Rinse, O₃ Marangoni Dry, HC1). During the duration between the wet-pretreatment and wafer loading, the substrate was maintained in a controlled low pressure atmosphere for less than one hour. The substrate was placed into a SiNgen® LPCVD chamber, available from Applied Materials, Inc. of Santa Clara, Calif., where a thin continuous amorphous silicon layer was deposited on the surface of the germanium substrate. Deposition of the amorphous silicon layer was achieved by exposing the germanium substrate to N₂ at a bottom flow rate of 3,500 sccm, N₂ at a top flow rate of 5,000 sccm, and SiH₄ at a flow rate of 30 sccm, at a temperature of 800° C., a pressure of 275 Torr, for a period of 6 seconds to deposit 23 Å of silicon at a deposition rate of 230 Å/min. A silicon dioxide layer was then deposited on the silicon layer by flowing N₂ at a bottom flow rate of 3,500 sccm, N₂ at a top flow rate of 5,000 sccm, SiH₄ at a flow rate of 15 sccm, and N₂O at a flow rate of 3,000 sccm, at a temperature of 800° C., a pressure of 275 Torr, for a period of 76 seconds to deposit 1526 Å of silicon oxide at a rate of 1,205 Å/min.

### Example 4

A silicon dioxide layer was formed on a germanium substrate with a silicon barrier layer therebetween. Initially a 200 mm germanium substrate formed by epitaxially depositing germanium was exposed to a pretreatment cleaning step using IMEC Clean #2 (SPM/O₃-HF-Rinse, O₃ Marangoni Dry, HC1). During the duration between the wet-pretreatment and wafer loading, the substrate was maintained in a controlled low pressure atmosphere for less than one hour. The substrate was placed into a SiNgen® LPCVD chamber, available from Applied Materials, Inc. of Santa Clara, Calif., where a thin continuous amorphous silicon layer was deposited on the surface of the germanium substrate. Deposition of the amorphous silicon layer was achieved by exposing the germanium substrate to N₂ at a bottom flow rate of 3,500 sccm, N₂ at a top flow rate of 5,000 sccm, and SiH₄ at a flow rate of 30 sccm, at a temperature of 800° C., a pressure of 275 Torr, for a period of 16 seconds to deposit 61 Å of silicon at a deposition rate of 229 Å/min. A silicon dioxide layer was then deposited on the silicon layer by flowing N₂ at a bottom flow rate of 3,500 sccm, N₂ at a top flow rate of 5,000 sccm, SiH₄ at a flow rate of 15 sccm, and N₂O at a flow rate of 3,000 sccm, at a temperature of 800° C., a pressure of 275 Torr, for a period of 76 seconds to deposit 1,526 Å of silicon oxide at a rate of 1,205 Å/min.

Hardware

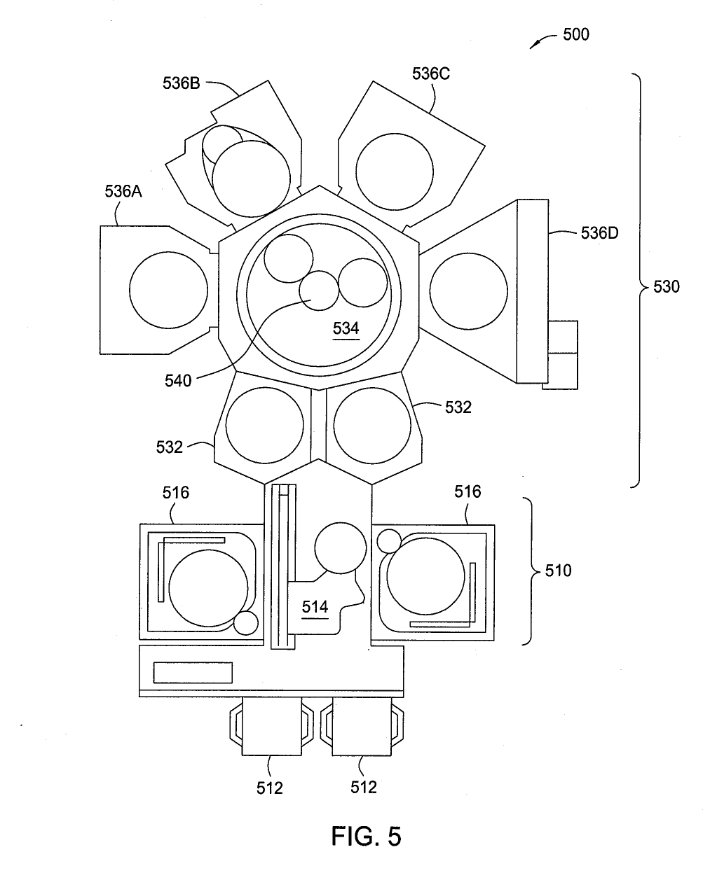

FIG. 5 is a schematic view of an exemplary integrated processing system 500 capable of performing the processes disclosed herein. The integrated processing system 500 comprises a cleaning module 510 and a thermal processing/deposition mainframe system 530. As shown in FIG. 5, the cleaning module 510 may be an OASIS CLEAN™ system, available from Applied Materials, Inc., located in Santa Clara, Calif. The thermal processing/deposition mainframe system 530 is a CENTURA® system and is also commercially available from Applied Materials, Inc., located in Santa Clara, Calif. This particular embodiment of the system is only illustrative and should not be used to limit the scope of the invention.

The cleaning module 510 generally includes one or more substrate cassettes 512, one or more transfer robots 514 disposed in a substrate transfer region, and one or more single-substrate clean chambers 516. Other aspects and embodiments of a single-substrate clean system are disclosed in U.S. patent application Ser. No. 09/891,849, entitled “METHOD AND APPARATUS FOR WAFER CLEANING,” filed Jun. 25, 2001, published as U.S. 2002-0029788, and herein incorporated by reference in its entirety to the extent not inconsistent with the present disclosure.

The thermal processing/deposition mainframe system 530 generally includes load lock chambers 532, a transfer chamber 534, and processing chambers 536A, 536B, 536C, and 536D. The transfer chamber 534 is preferably maintained from between 1 mTorr to about 100 Torr and preferably comprises a non-reactive gas ambient, such as a N₂ ambient. The load lock chambers 532 allow for the transfer of substrates into and out from the thermal processing/deposition mainframe system 530 while the transfer chamber 534 remains under a low pressure non-reactive environment. The transfer chamber includes a robot 540 having one or more blades which transfers the substrates between the load lock chambers 532 and processing chambers 536A, 536B, 536C, and 536D. Any of the processing chambers 536A, 536B, 536C, or 536D may be removed from the thermal processing/deposition mainframe system 530 if not necessary for the particular process to be performed by the system 530.

It is believed that it is advantageous to perform the pre-treatment step 120, the barrier layer formation step 130, and the dielectric layer formation step 140 on a mainframe system to reduce the formation of native oxides and/or contamination of the pre-treated surface of a substrate prior to formation of the barrier layer and dielectric layer. It is optional to have the cleaning module 510 coupled with mainframe system 530 as shown in FIG. 5 to further reduce the formation of native oxides over and/or contamination of substrates between cleaning steps and other processing steps. Of course, in other embodiments, cleaning steps may be performed in a cleaning module separate from the thermal processing/deposition mainframe system.

One embodiment of the integrated processing system 500 configured to form a dielectric layer on a germanium substrate comprises a first processing chamber 536A adapted to perform a Decoupled Plasma Nitridation process. A second processing chamber 536B comprises a rapid thermal processing (RTP) chamber where the structure may be annealed. The RTP chamber may be a RADIANCE®, RADIANCE Plus, or RADIANCE XE Plus system available from Applied Materials, Inc. The third processing chamber 536C comprises a low pressure chemical vapor deposition chamber (LPCVD), such as a POLYGEN™ chamber, available from Applied Materials, Inc, adapted to deposit an amorphous silicon layer. The fourth processing chamber 536D may also comprise a LPCVD chamber, such as the SiNgen® system, available from Applied Materials, Inc. of Santa Clara, Calif. In certain embodiments, an atomic layer deposition chamber, adapted to deposit a dielectric material, may also be included in the system. Other embodiments of the system 500 are within the scope of the present invention. For example, the position of a particular processing chamber on the system may be altered or the number of processing chamber may be altered.

Without intending to be limited by any particular theory of invention, it is believed that formation of a barrier layer on the surface of a germanium substrate prior to deposition of dielectric layer, reduces the formation of germanium oxides, thus producing a high quality silicon oxide film deposited on a germanium substrate.

While the foregoing is directed to embodiments of the present invention, other and further embodiments of the invention may be devised without departing from the basic scope thereof, and the scope thereof is determined by the claims that follow.

1. A method for forming a dielectric film on a germanium substrate, comprising:
providing the germanium substrate within a process chamber;
forming a barrier layer on the germanium substrate; and
forming a dielectric layer on the barrier layer.

2. The method of claim 1, wherein the barrier layer comprises an amorphous silicon layer.

3. The method of claim 1, wherein the barrier layer comprises a silicon nitride layer.

4. The method of claim 1, wherein the barrier layer comprises a germanium nitride layer formed by exposing the germanium substrate to a plasma nitridation process.

5. The method of claim 1, wherein the dielectric layer comprises a silicon dioxide layer.

6. The method of claim 5, further comprising incorporating nitrogen into the silicon dioxide layer to form a silicon oxynitride layer.

7. The method of claim 3, wherein forming the silicon nitride layer on the substrate comprises exposing the substrate to a first deposition gas comprising silane and a carrier gas.

8. The method of claim 7, further comprising exposing the substrate to a second deposition gas comprising a nitrogen source selected from the group comprising NO, N₂O, N₂, NH₃, and N₂H₄.

9. A method for forming a dielectric film on a germanium substrate, comprising:
providing a germanium substrate;
depositing a silicon layer on the germanium substrate; and
forming a silicon dioxide layer on the silicon layer.

10. The method of claim 9, wherein the forming a silicon oxide layer on the silicon layer comprises annealing the silicon layer in oxygen containing atmosphere.

11. The method of claim 9, wherein the silicon layer has a thickness between about 20 Å and about 100 Å.

12. The method of claim 9, wherein the silicon dioxide layer has a thickness between about 1000 Å and about 1600 Å.

13. The method of claim 9, wherein forming the silicon layer on the substrate comprises exposing the substrate to a first silicon containing deposition gas at a flow rate from about 10 sccm to about 30 sccm, an oxygen containing gas at a flow rate from about 1,000 sccm to about 10,000 sccm, and a carrier gas.

14. The method of claim 13, wherein the carrier gas is selected from the group consisting of hydrogen, argon, nitrogen, helium, and combinations thereof.

15. The method of claim 9, further comprising heating the substrate to a range from about 700° C. to about 800° C. at a pressure within a range from about 200 Torr to about 300 Torr.

16. A method for forming a dielectric film on a germanium substrate, comprising:
providing a germanium substrate;
exposing the germanium substrate to a plasma comprising a nitrogen source to form a germanium nitride layer; and
forming a dielectric layer on the germanium nitride layer.

17. The method of claim 16, wherein the nitrogen source is selected from the group consisting of N₂, NO, N₂O, and NH₃.

18. The method of claim 16, wherein the germanium nitride layer has a thickness between about 50 Å and about 200 Å.

19. The method of claim 16, wherein the dielectric layer is a silicon oxide layer.

20. The method of claim 19, further comprising incorporating nitrogen into the dielectric layer to form a silicon oxynitride layer.
